(19) United States
(12) Patent Application Publication
(10) Pub. No.: US 2012/0003438 A1
(43) Pub. Date: Jan. 5, 2012

(54) GRAPHENE PROCESSING FOR DEVICE AND SENSOR APPLICATIONS

(75) Inventors: Bill R. Appleton, Gainesville, FL (US); Brent P. Gila, Gainesville, FL (US)

(73) Assignee: UNIVERSITY OF FLORIDA RESEARCH FOUNDATION, INC., Gainesville, FL (US)

(21) Appl. No.: 13/202,136

(22) PCT Filed: Feb. 19, 2010
(86) PCT No.: PCT/US10/24723

§ 371 Date: Sep. 20, 2011

Related U.S. Application Data
(60) Provisional application No. 61/154,137, filed on Feb. 20, 2009.

(51) Int. Cl. B32B 3/10; B05D 3/10; B05D 3/04; B05D 3/06; H01L 21/30; B05D 5/12

(52) U.S. Cl. 428/195.1; 438/758; 427/122; 427/532; 427/534; 216/13; 257/E21.211; 977/734

(57) ABSTRACT

A supported graphene device comprises at least one graphene feature of 1 to about 10 graphene layers having a predetermined shape and pattern, with at least a portion of each graphene feature being supported on a substrate. In some embodiments the device comprises graphene features supported on crystalline semiconductor substrate, such as silicon or germanium. The graphene features on a crystalline semiconductor substrate can be fabricated by forming an amorphous carbon doped semiconductor on the crystalline semiconductor substrate and then epitaxially crystallizing the amorphous semiconductor with carbon migration to the surface to form a graphene feature of one or more graphene layers. The epitaxy can be promoted by heating the device or by irradiation with a laser. Methods for fabricating graphene on a variety of substrates, over large areas with controlled thicknesses employ ion implantation or other doping techniques followed by pulsed laser annealing or other annealing techniques that result in solid phase regrowth are presented.

### CROSS-REFERENCE TO A RELATED APPLICATION

This application claims the benefit of U.S. Provisional Application Ser. No. 61/154,137, filed Feb. 20, 2009, the disclosure of which is hereby incorporated by reference in its entirety, including all figures, tables and drawings.

### BACKGROUND OF THE INVENTION

Recently the discovery of graphene, atomically thin layers of graphite (Novoselov et al. “Electric Field Effect in Atomically Thin Carbon Films.” Science 2004, 306(5696): 666-9) allowed the isolation of a single two-dimensional atomic layer of atoms. The strongest covalent bond in nature, the C—C bond, locks these atoms into an array with remarkable mechanical properties (Meyer et al. “The Structure of Suspended Graphene Sheets” Nature 2007, 446(7131) 60-3). A single layer of graphene is one of the stiffest known materials, characterized by a remarkably high Young's modulus of ˜1,000 GPa (Bunch et al. “Electromechanical Resonators from Graphene Sheets” Science 2007, 315(5811) 490-3). A graphene membrane is impermeable to gases, down to the thickness limit of one atomic layer (Bunch et al. “Impermeable Atomic Membranes from Graphene Sheets” Nano Lett. 2008, 8(8), 2458-62). As an electronic material, graphene allows consideration of electrons in 2, 1, and 0 dimensions where properties are novel due to its linear band structure. Scattering is low in graphene, which allows the observation of the Quantum Hall Effect (QHE) (Zhang et al. “Experimental Observation of the Quantum Hall Effect and Berry's Phase in Graphene” Nature 2005 438(7065) 201-4). Hence, graphene is emerging as an enormously promising material for: solid state chemical, gas and biological sensors; nanoelectronics (including FETs, SETs, spin valves, and superconducting FETs); logic and memory; field emitters for plasma displays; batteries; spin qbits; Hall effect devices; and conducting composite materials in addition to their use for fundamental QED studies. Fabrication of continuous, large areas of graphene remains a barrier to the introduction of graphene into devices of these types.

The most common method of graphene fabrication is exfoliation, which is a technique derived from writing with a graphite pencil where many sheets of graphene that are deposited in thicknesses of varied numbers of graphene layers are spread over paper. Novoselov et al. discloses a modification of this approach where a freshly cleaved graphite crystal is gently rubbed on an oxidized silicon wafer having a specific thickness of oxide to yield graphene flakes as single atomic layers that can be observed visibly under an optical microscope due to thin film interference effects. This technique allows one to find single graphene sheets, but is limited to only the tedious fabrication of devices for research purposes. There have been attempts to improve the quality and yield of exfoliated graphene, including using sticky tape to peel graphene layers and transfer them to a substrate, stamping methods that use silicon pillars to transfer graphene flakes (Liang et al. “Graphene Transistors Fabricated via Transfer-Printing in Device Active-Areas on Large Wafer” Nano Lett. 2007 7(12) 3840-4) and electrostatic voltage assisted exfoliation, which uses electrostatic forces to controllably separate graphene from bulk crystals (Sidorov et al. “Electrostatic Deposition of Graphene” Nanotechnology 2007 (13): 135301).

Another graphene fabrication technique is to disperse graphene from solution (Bunch et al. “Coulomb Oscillations and Hall Effect in Quasi-2D Graphite Quantum Dots” Nano Lett. 2005 5(2) 287-90). This method uses the sonication of graphite flakes in solution and then dispersed of the flakes onto a wafer. An atomic force microscope (AFM) is used to locate individual sheets, which is a very time cons uming method relative to the optical detection used for exfoliated graphene. Long sonication times are needed to yield small single layer graphene flakes. A similar technique allows for the fabrication of graphene ribbons with nm-scale widths (Li et al. “Chemically Derived, Ultrasmooth Graphene Nanoribbon Semiconductors” Science 2008 319(5867) 1229-32). One difficulty inherent to methods of dispersing graphene in solution is the separation of the layers without breaking the layers.

A technique that appears to have some potential for mass production of graphene involves heating a SiC wafer to high temperatures to partially graphitize the upper layer or layers (Berger et al. “Ultrathin Epitaxial Graphite: 2D Electron Gas Properties and a Route Toward Graphene-Based Nanoelectronics” J. Phys. Chem. B 2004 108(52) 19912-6). However, controlling the number of graphene layers and the grain sizes is difficult and has yielded limited success at achieving graphene with good mobilities (Berger et al. “Electronic Confinement and Coherence in Patterned Epitaxial Graphene” Science 2006 312(5777) 1191-6 and Hass et al. “Why Multilayer Graphene on 4H—SiC(0001) Behaves Like a Single Sheet of Graphene” Phys. Rev. Lett. 2008, 100, 125504). Furthermore, isolating single graphene sheets is problematic as the graphene sheet is not readily isolated from the SiC substrate.

Exfoliation remains the preferred method for most experimental research groups around the world. Wide spread applicability of graphene is limited by the crude time consuming methods currently used to fabricate and isolate single graphene sheets. There remains a need to develop a reliable and reproducible graphene fabrication method that is compatible with commercial semiconductor device fabrication techniques if graphene is to move beyond being a laboratory curiosity.

### BRIEF SUMMARY OF THE INVENTION

Embodiments of the invention are directed to supported graphene devices where a substrate supports at least a portion of each of at least one graphene feature with the features have a predetermined shape and pattern. Each graphene feature independently has 1 to about 10 graphene layers. The substrate can be: a crystalline semiconductor, such as silicon or germanium: a compound semiconductor, such as metal arsenide, phosphide, nitride, oxide or carbide; a single crystalline or polycrystalline metal or metal alloy; an insulator; or a superconductor. The graphene features can be self supported, partially supported or fully supported by the substrate. The graphene features can independently be predominately or exclusively carbon 12, carbon 13, or carbon 14. The graphene features can be independently doped or, where the feature is a plurality of graphene layers, the layers can be intercalated.

Other embodiments of the invention are directed to methods of forming supported graphene where a substrate has at least one carbon doped substrate feature formed by doping at least one portion of the substrate with carbon on or within the substrate and the carbon doped substrate features are epitaxially converted to additional substrate and graphene features of, independently, 1 to about 10 graphene layers residing upon the substrate. The carbon doped substrate features can be formed by ion implantation of carbon into the substrate proximal to a targeted surface. The amorphous carbon doped substrate features can be forming by chemical vapor deposition on a targeted surface of the substrate. The features can be converted into the supported graphene by heating the feature and the substrate to a sufficient temperature that an amorphous-crystalline interface epitaxially migrates towards the surface to ultimately form the substrate supported graphene layer or layers. The epitaxy can be promoted by irradiation of the volume in and adjacent to the amorphous carbon doped substrate features using a laser beam. As and when needed, the surface upon which the graphene is ultimately formed can be cleaned by wet chemical etching, plasma etching, or low energy ion bombardment etching. The substrate can be selectively etched from underneath the graphene features to form a graphene feature that is self supported or partially supported by the substrate. The graphene features can be doped or when the feature has a plurality of graphene layers, intercalated.

### BRIEF DESCRIPTION OF THE DRAWINGS

FIG. 1 illustrates the steps of forming a graphene features supported by a substrate according to an embodiment of the invention where (a) the substrate is ion implanted with carbon to give (b) an amorphous carbon doped substrate feature where the carbon depth profile is given in a graph superimposed on the upper left portion of the doped substrate image. The amorphous carbon doped substrate feature is heated (c) to anneal the substrate where a graph of the evolving carbon depth profile is superimposed on the upper left portion of the doped substrate image, and ultimately, after sufficient migration occurs, (d) the substrate supported graphene feature is formed.

### DETAILED DESCRIPTION OF THE INVENTION

One embodiments of the invention is directed to methods for fabricating graphene layers of a controlled-thickness over large areas on a substrate. Another embodiment of the invention is directed to methods for fabricated patterned graphene layers of a controlled-thickness. Other embodiments of the invention are directed to devices useful for sensor or other applications that are formed by these methods of forming graphene layers. The devices can be fabricated using conventional semiconductor technologies or ion beam processing methods, see for example Ion Implantation and Beam Processing, J. S. Williams et al., ed., Academic Press 1984, where the graphene layers form single device features or integrated circuits.

In one embodiment of the invention, solid phase epitaxy (SPE) is employed on a substrate that has ion implanted carbon. By heating a single crystalline carbon implanted silicon or germanium in the volume near the surface to elevated temperatures, for example 500° C. to 1,000° C., in vacuum or a controlled inert atmosphere, the carbon segregates to the surface. Using a controlled implantation process, a silicon crystal can be rendered amorphous to the depth of the implanted carbon ions, where the depth of the carbon doping can be accurately controlled by adjusting the energy of implantation. The amount of carbon can be controlled precisely to a fraction of a graphene monolayer. At elevated temperatures the amorphous silicon layer containing the carbon crystallizes on the underlying crystalline silicon lattice by SPE and the carbon migrates along the amorphous layer in front of the advancing crystalline interface as a result of differences in the thermodynamic and materials properties of carbon and silicon. Ultimately the carbon is segregated at the surface of the silicon sample and forms a single or multiple graphene layers.

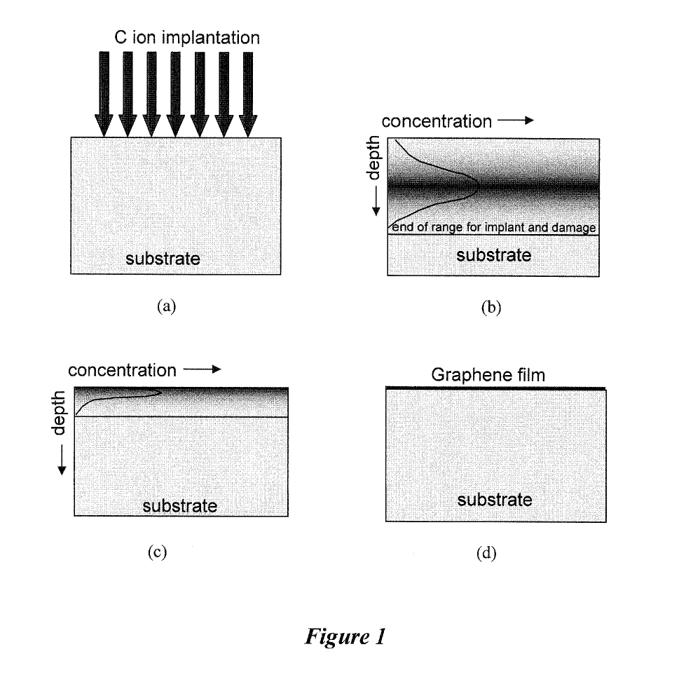

The number of graphene layers that are formed depends on the concentration of carbon implanted and the annealing conditions. The rate of the carbon interface migration depends upon the carbon doping level, temperature, underlying silicon crystal structure, and interfacial interactions. The graphene layers can be formed over the entire implanted area. FIG. 1 illustrates a process of ion implantation where (a) ion implantation to a surface of a crystalline substrate results in (b) an amorphous region that exhibits a distribution of carbon atoms doped in the vicinity of the surface where (c) annealing causes migration of carbon such that it concentrates at the surface until (d) the carbon ultimately segregates into a graphene layer on a crystalline substrate. In some embodiments the silicon surface can be cleaned before ion implantation and/or before annealing by using a buffered etch, or other technique that removes surface oxygen and any other surface impurities. Numerous conventional surface cleaning methods can be employed, including but not limited to acid etching, low energy ion sputtering in vacuum or plasma cleaning.

Ion implantation, as illustrated in FIG. 1, allows an accurate control of the resulting concentration of carbon and the resulting thickness of the carbon that segregates to the surface by controlling the implantation dose. Ion implantation also allows accurate control of the area covered by the resulting graphene film by control of the area on the substrate surface that is implanted. In one embodiment of the invention, isotopically pure carbon 12 or carbon 13 graphene layers are grown at different areas of the surface of implanted substrates such that isotope effects may be exploited to differentiate the implanted areas on devices. Having two distinct and identifiable graphene areas can be exploited for fundamental investigations of material and other applications where it is advantages to have two distinct and identifiable carbon species.

The substrate used for the process, illustrated in FIG. 1, is not limited to single crystal Si and Ge, but can be extended to other substrates. Other single crystal semiconductors, for example compound semiconductors, oxides, nitrides, and carbides are possible substrates. The process can be applied to metal substrates that are either pure metals or metal alloys that are single crystals or polycrystalline yet allow carbon to segregate to the surface. Exemplary metals include Ni and Ir. With these substrates, ion implantation results in the deposition of carbon very near the substrate surface, where in spite of the lack of crystalline/amorphous interface to promote diffusion of all carbon to the surface, the rate of diffusion of carbon to the surface is significantly greater than that for diffusion into the underlying bulk, such that one can still accurately control the amount of carbon that segregates to the surface. In some embodiments of the invention, the amorphous carbon doped silicon or other carbon doped material is prepared by carbon ion implantation. In other embodiments of the invention preparation of a carbon doped layer in a material can be formed by alternate means. For example, chemical vapor deposition of silane and acetylene, as disclosed in Simonelli el al., U.S. Patent Application Publication 2008/0242061, can be used to form a carbon doped silicon film. Any methods that permits deposition of an amorphous carbon doped material where precise control of the amount of carbon doped into the material is possible can be used to form the carbon doped material according to embodiments of the invention.

In embodiments of the invention, the annealing step can be carried out with a pulsed or continuous scanned laser to form at least one graphene layer on the surface of a substrate material. For example, a silicon single crystal can be surface-cleaned and ion implanted with carbon at a dose to yield a desired graphene layer thickness. The carbon implanted silicon substrate can be placed in a vacuum or inert environment and a uniform laser beam is used to irradiate a surface of the substrate. Laser pulses from an excimer (249 nm, 25 ns, 0.5-2 J/cm²), ruby (694 nm, 15 ns, 1-2 J/cm²), or YAG (1060 nm, 1-3 J/cm²) lasers or a variety of other pulsed lasers are suitable for use in embodiments of the invention. A continuous laser can be scanned over the entire area where graphene is to be formed on the substrate. When annealing is carried out using a pulsed laser, the energy from the laser pulse is absorbed by the silicon which induces melting. Depending on the energy of the pulse, the silicon can be melted beyond the volume of the implanted carbon ions. Because the surface melted region is shallow, the heat is conducted away from the site of irradiation by the underlying solid silicon crystal and the liquidized silicon atoms undergo crystal growth on the underlying crystal lattice by liquid phase epitaxial (LPE). As the liquid-solid interface migrates to the surface, the carbon atoms are rejected from the molten layer at the front of the moving solid interface. Depending on the annealing (LPE) conditions, the interface velocity can range from 1-20 m/sec. Ultimately, the implanted carbon is segregated to the surface in the form of a graphene layer or layers with the graphene thickness determined by the initial ion implantation dose. By controlling the energy of the lasers one can promote surface melting and rapid solidification by SPE or rapid surface annealing in the solid phase. A wide variety of materials can be used as the substrate as long as the laser annealing conditions are known or can be determined, and where the thermodynamic and materials properties of carbon in the substrate permits segregation of carbon to the surface on annealing, as taught in Laser-Solid Interactions and Laser Processing—1978, S. D. Ferris et al. ed., AIP Conference Proceedings Number 50, New Your 1979 or Laser and Electron Beam Processing, C. W. White et al., Academic Press 1980.

Ion implantation doping combined with pulsed laser annealing, solid phase epitaxy, and/or thermal processing also provides the capability to create non-equilibrium conditions that are not possible with normal processing methods. As any ion can be implanted into any substrate material, and because the conditions in a single ion cascade are highly non-equilibrium (see Ion Implantation and Beam Processing, J. S. Williams et al., ed. Academic Press 1984) it is possible to create metastable conditions and control the thermal processing times. By implanting carbon very near the surface of a substrate in a thin layer, it is possible to heat and cool the surface region very rapidly (such as with a pulsed laser or rapid thermal annealing) or in an equilibrium manner, where by controlling the processing times (quench rates) graphene layers can be formed on some substrates where it would otherwise not be possible. Methods employing carbon ion implantation and laser or rapid thermal annealing are compatible with currently employed semiconductor processing methods, and can be readily implemented in a process. The dose of carbon implanted into the material per unit surface area where epitaxy is carried out defines the number of graphene layers that can ultimately segregate to the surface which results in the properties of the device for a given substrate.

A single graphene layer can be formed and the device can display the behavior of a zero-gap semiconductor with single electron and hole types. Three graphene layers can be formed for devices where other conduction, valence band and charge carriers properties are desired. Ten graphene layers results in a surface having the properties of bulk graphite.

Once formed, a single graphene layer can be doped and, when a plurality of graphene layers is formed, intercalation can be carried out to modify the electrical and/or material properties. For example, the graphene can be treated with a halogen, nitric acid, or other known doping agents for graphene or other conductive carbons, such as those known to dope carbon nanotubes. Virtually any dopant atoms can be introduced by low energy ion implantation, deposition and rapid thermal annealing, deposition and diffusion, or other well known techniques. Because of the wide selection of dopants, intecalants, and substrates, it is possible to achieve a host of different properties for a desired device. For example, a magnetic dopant atom such as manganese, gadolinium, or cobalt can be introduced to develop a magnetically coupled device based on electron spin called a “spintronic.” Graphene layers can be prepared with defects to enhance sensitivities or to tailor catalytic effects. Like any electronic or sensor materials, defects can alter properties and lead to more desirable interactions for selected applications. Defects can be introduced into the graphene layer in various way including: doping; creating structural defects in the deposition or annealing process; creating strain between the deposited graphene layer(s) and the underlying substrate through lattice mismatch; by direct ion bombardment with selected ions; or a variety of other method for introduction of defects into solids. Where a plurality of graphene features are supported on a substrate, features can be commonly doped or intercalated or selected features can be selectively doped or intercalated.

Another embodiment of the invention is the creation of thin self supported graphene layers for selected applications. As graphene is a very strong material, a layer of one or more graphene sheets can extend over areas of a few square microns where most of the layer is not directly in contact with a substrate, but rather it is suspended from at least one small area of substrate. In this manner, a graphene layer is considered self supported where a majority of the area of the graphene layer is not in direct contact with the substrate yet the graphene layer maintains its shape. For purposes of the invention a self supported graphene feature has less than 50% of the graphene feature residing on a substrate, a partially supported graphene feature has more than 50% of the graphene feature residing on a substrate, and a supported graphene feature has the entire graphene layer residing on the substrate. When silicon is used as the substrate for the epitaxial growth of the graphene layers, the graphene layer can be made self supported on the silicon substrate by chemical etching methods. For example, a number of etchants preferentially etch silicon but do not etch graphite or graphene, for example, when an ethylene diamine-pyrocatechol (EDP) etchant protocol or a tetramethylammonium hydroxide (TMAH) etchant protocol is employed.

Because of the strength of graphene, a large area window can be created that is self-supporting on an underlying thick silicon substrate. It is also possible to create a graphene layer on a thin silicon window, where both are supported by an underlying thick silicon substrate. For example, a silicon single crystal can be implanted with boron and carbon prior to annealing. Upon annealing, boron becomes incorporated into substitutional sites in the silicon substrate as it re-crystallizes and the carbon segregates to the surface. A selective backside etch of the silicon can be stopped when the etchant encounters the boron-doped layer, leaving the graphene layer supported on a thin silicon window. For appropriate etchants and procedures see N. W. Cheung, “Preparation of large-area monocrystalline silicon thin windows,” Rev. Sci. Instrum. 1980 51(9), 1212-6. Other selective etching methods for other substrate materials can be employed to produce self supporting graphene layers. Exemplary methods for etching a wide variety of substrates are given in Williams et al. “Etch Rates for Micromachining Processing Part II” J. Microelectromechanical Systems 2003, 761-8.

All patents, patent applications, provisional applications, and publications referred to or cited herein, supra or infra, are incorporated by reference in their entirety, including all figures and tables, to the extent they are not inconsistent with the explicit teachings of this specification.

It should be understood that the examples and embodiments described herein are for illustrative purposes only and that various modifications or changes in light thereof will be suggested to persons skilled in the art and are to be included within the spirit and purview of this application.

1. A supported graphene device comprising:
a substrate; and
at least one graphene feature having a predetermined shape and pattern, wherein each graphene feature independently comprises 1 to about 10 graphene layers and wherein the graphene feature is self-supported, partially supported or fully supported on the substrate.

2. The supported graphene device of claim 1, wherein the substrate consists of a crystalline semiconductor.

3. The supported graphene device of claim 2, wherein the semiconductor is silicon or germanium.

4. The supported graphene device of claim 2, wherein the semiconductor is a compound semiconductor comprising a metal arsenide, phosphide, nitride, oxide or carbide.

5. (canceled)

6. The supported graphene device of claim 1, wherein the substrate comprises a single crystalline or polycrystalline metal or metal alloy.

7. The supported graphene device of claim 1, wherein the substrate comprises an insulator.

9. The supported graphene device of claim 1, wherein each of the graphene features has an equivalent number of the graphene layers.

10. The supported graphene device of claim 1, wherein the substrate supports a plurality of graphene features and wherein each graphene feature independently comprises a single isotope of carbon.

11. The supported graphene device of claim 1, wherein the graphene feature is doped or intercalated.

12. A method for formation of supported graphene comprising the steps of:
providing a substrate;
forming a pattern of at least one amorphous carbon doped substrate feature on the substrate; and
converting the amorphous carbon doped substrate feature to additional substrate and a graphene feature comprising 1 to about 10 graphene layers residing upon the substrate.

13. The method of claim 12, wherein the substrate is wherein the substrate consists of a crystalline semiconductor.

14. The method of claim 13, wherein the semiconductor is silicon or germanium.

15. The method of claim 13, wherein the semiconductor is a compound semiconductor comprising a metal arsenide, phosphide, nitride, oxide or carbide.

16. (canceled)

17. The method of claim 12, wherein the substrate comprises a single crystalline or polycrystalline metal or metal alloy.

18. The method of claim 12, wherein the substrate comprises an insulator.

19. The method of claim 12, wherein the substrate comprises a superconductor.

20. The method of claim 12, wherein the step of forming comprises ion implantation of carbon into the substrate proximal to a targeted surface.

21. The method of claim 12, wherein the step of forming comprises chemical vapor deposition on a targeted surface.

22. The method of claim 12, wherein the step of converting comprises heating the feature and the substrate to a sufficient temperature wherein an amorphous-crystalline interface migrates towards the surface to form the 1 to about 10 graphene layers of the graphene feature upon the substrate.

23. The method of claim 12, wherein the step of converting comprises irradiating the volume in and adjacent to the amorphous carbon doped substrate features with a laser beam in, wherein an amorphous-crystalline interface migrates towards the surface to form the 1 to about 10 graphene layers of the graphene feature upon the substrate.

24. The method of claim 12, further comprising the step of cleaning the surface of the amorphous carbon doped substrate features.

25. The method of claim 24, wherein the step of cleaning comprises wet chemical etching, plasma etching, or low energy ion bombardment etching.

26. The method of claim 12, further comprising the step of etching the substrate from underneath a portion of the graphene features.
